(19) United States
(12) Patent Application Publication
(10) Pub. No.: US 2024/0231078 A1
(43) Pub. Date: Jul. 11, 2024

(54) MICRO-MIRROR FRINGE FIELD ELECTRODE DESIGN WITH MISALIGNMENT COMPENSATION

(71) Applicant: Texas Instruments Incorporated, Dallas, TX (US)

(72) Inventors: William McDonald, Allen, TX (US); James Hall, Parker, TX (US)

(21) Appl. No.: 18/397,677

(22) Filed: Dec. 27, 2023

Related U.S. Application Data
(60) Provisional application No. 63/478,510, filed on Jan. 5, 2023.

(51) Int. Cl. G02B 26/08; B81B 3/00

(52) U.S. Cl. CPC G02B 26/0841; B81B 3/0056; B81B 2201/042; B81B 2203/04

(57) ABSTRACT

In one example, an apparatus includes a substrate, an electrode layer on the substrate, and a hinge layer. The electrode layer has N linear electrode edges on a side of a centerline of the electrode layer, N being an odd number greater than or equal to 3. The hinge layer has N linear hinge edges on the side of the centerline. A first edge of the linear hinge edges is spaced apart from a closest second edge of the linear electrode edges by a first lateral gap distance. A third edge of the linear hinge edges is spaced apart from a closest fourth edge of the linear electrode edges by a second lateral gap distance different from the first lateral gap distance.

### RELATED APPLICATIONS

The present application claims priority to U.S. Provisional Patent Application No. 63/478,510, titled “MICRO-MIRROR FRINGE FIELD ELECTRODE DESIGN WITH MISALIGNMENT COMPENSATION,” Attorney Docket No. T102699US01, filed Jan. 5, 2023, which is hereby incorporated by reference in its entirety.

### BACKGROUND

Actuators are used in various technologies. For example, actuators may be used in spatial light modulators to spatially modulate a beam of light. Some microelectromechanical actuator systems include an array of movable pixels that can change the intensity and/or phase of an incident beam of light. Microelectromechanical actuator systems are used in, for example, high dynamic range cinema, light detection and ranging systems, high volume optical switching (e.g., used in telecom or server farms), microscopy, spectroscopy, adaptive optics, holographic displays, other projection displays, and other light control applications.

### SUMMARY

In one example, an apparatus includes a substrate, an electrode layer on the substrate, and a hinge layer. The electrode layer has N linear electrode edges on a side of a centerline of the electrode layer, N being an odd number greater than or equal to 3. The hinge layer has N linear hinge edges on the side of the centerline. A first edge of the linear hinge edges is spaced apart from a closest second edge of the linear electrode edges by a first lateral gap distance. A third edge of the linear hinge edges is spaced apart from a closest fourth edge of the linear electrode edges by a second lateral gap distance different from the first lateral gap distance.

In another example, an apparatus includes a substrate, an electrode layer on the substrate, and a hinge layer coupled to the electrode layer. The electrode layer has N linear electrode edges on a side of a centerline of the electrode layer, N being an odd number greater than or equal to 3. The hinge layer has N linear hinge edges on the side of the centerline. A first edge of the linear hinge edges is spaced apart from a closest second edge of the linear electrode edges by a first lateral gap distance substantially equivalent to a fixed distance plus an offset. A third edge of the linear hinge edges is spaced apart from a closest fourth edge of the linear electrode edges by a second lateral gap distance substantially equivalent to the fixed distance minus the offset.

In another example, an apparatus includes a substrate, an electrode layer on the substrate, a hinge layer, a mirror layer, and first and second posts. The electrode layer has N linear electrode edges on a side of a centerline of the electrode layer, N being an odd number greater than or equal to 3. The hinge layer has N linear hinge edges on the side of the centerline. The first post couples the hinge layer to the electrode layer. The second post couples the mirror layer to the hinge layer. A first edge of the linear hinge edges is spaced apart from a closest second edge of the linear electrode edges by a first lateral gap distance. A third edge of the linear hinge edges is spaced apart from a closest fourth edge of the linear electrode edges by a second lateral gap distance different from the first lateral gap distance.

### BRIEF DESCRIPTION OF THE DRAWINGS

FIG. 1 is an exploded oblique view of an example pixel.

FIG. 2 is a view of the outlines of various layers of the pixel of FIG. 1.

FIG. 3 is a top-down view of an alternative pixel having square outer dimensions and three pairs of linear edges on a side of a centerline.

FIG. 4 is a top-down view of an alternative pixel having square outer dimensions and five pairs of linear edges on a side of a centerline.

FIG. 5 is a cross-sectional view of a portion of the pixel of FIG. 1 under an aligned condition.

FIG. 6 is a cross-sectional view of a portion of the pixel of FIG. 1 under a misaligned condition.

FIGS. 7A-7B show respective example states of the pixel of FIG. 1, which are responsive to the application of electric signals creating fringe-field electrostatic potential.

FIG. 8 is a matrix showing comparative representations of four example pixels, each applying either compensated or uncompensated lateral gaps under either an aligned or misaligned condition.

The same reference numbers or other reference designators are used in the drawings to designate the same or similar (functionally and/or structurally) features. The figures are not necessarily drawn to scale.

### DETAILED DESCRIPTION

Disclosed herein are various micromechanical electrostatic actuators having micromirror pixels that can move in a manner that changes the intensity and/or phase of an incident beam of light. Certain piston-type actuators, for example, can move micromirror pixels in an up and down fashion, such that the micromirrors are displaced by a fraction of a wavelength of the light source. Fringe-field electrostatics can be used to cause pixel actuation, wherein parallel electrode layers that do not overlap with one another receive respective electrical signals that cause an electrostatic potential therebetween. As described further below, the use of asymmetrical lateral gap spacing between nonoverlapping electrode layers can have certain technical advantages including, for example, increasing the maximum displacement distance of a micromirror, decreasing the risk of a collapse or “pull in” condition where different pixel layers at different electrostatic potentials contact one another, and decreasing the risk of undesired tilt that might otherwise be caused be certain misalignment conditions between pixel layers.

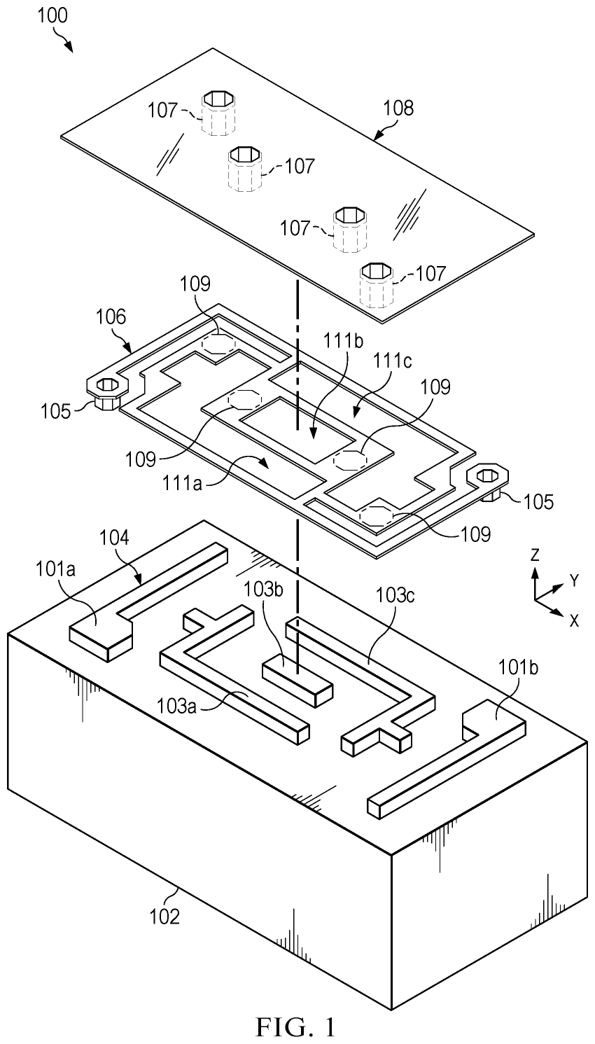

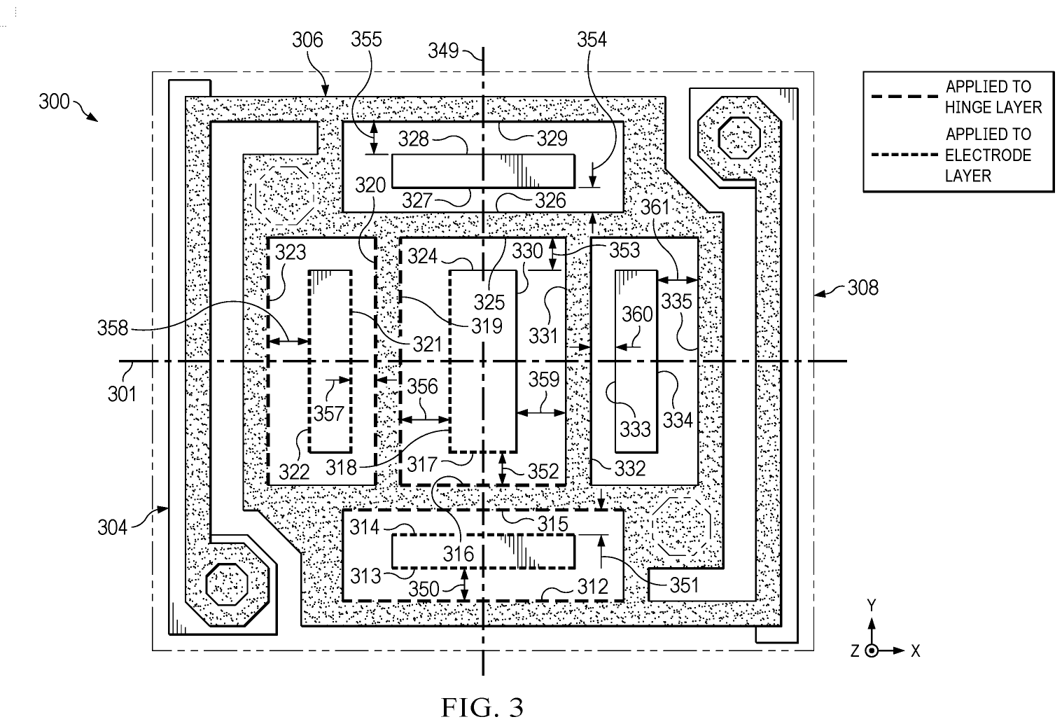

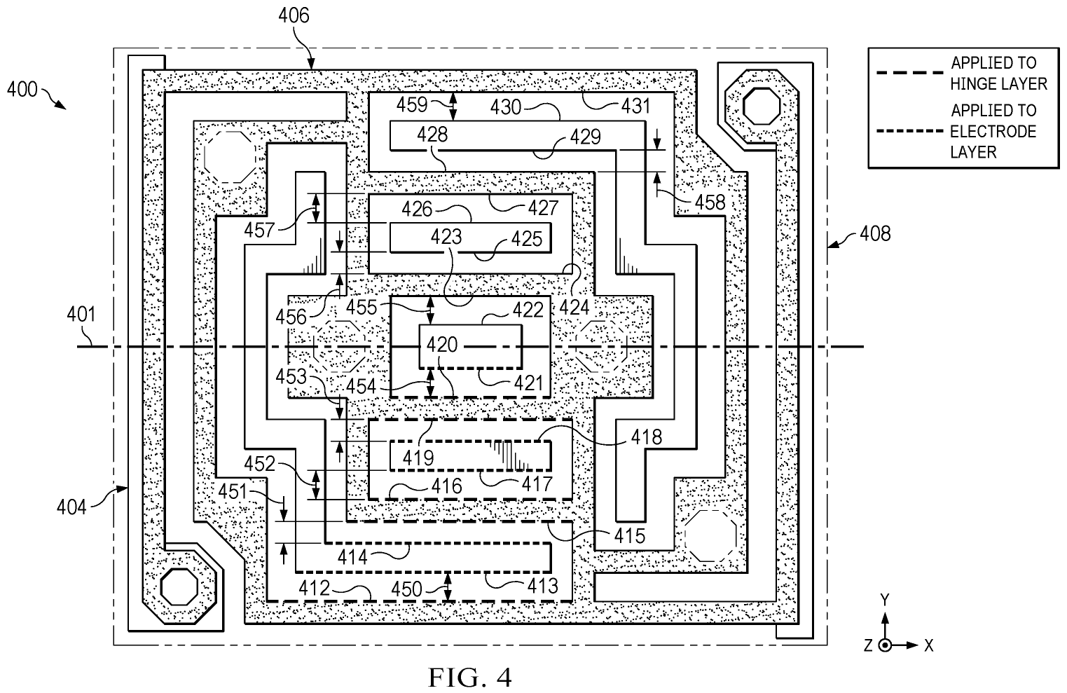

FIG. 1 is an exploded oblique view of an example pixel 100. In this example, pixel 100 includes a substrate 102, an electrode layer 104 on the substrate 102, a hinge layer 106 coupled to the electrode layer 104 (e.g., through one or more hinge posts 105), and a mirror layer 108 coupled to the hinge layer 106 (e.g., through one or more mirror posts 107). Mirror layer 108 includes a rectangular-shaped mirror. However, pixel 100 may have an outward-facing surface with any suitable shape, such as, for example, the square-shaped mirrors shown in FIGS. 3 and 4.

Hinge posts 105 physically and conductively couple hinge layer 106 to respective portions of electrode layer 104. One or more mirror posts 107 physically and conductively couple mirror layer 108 to hinge layer 106 and support mirror layer 108 above hinge layer 106. The mirror posts 107 encounter hinge layer 106 at locations 109.

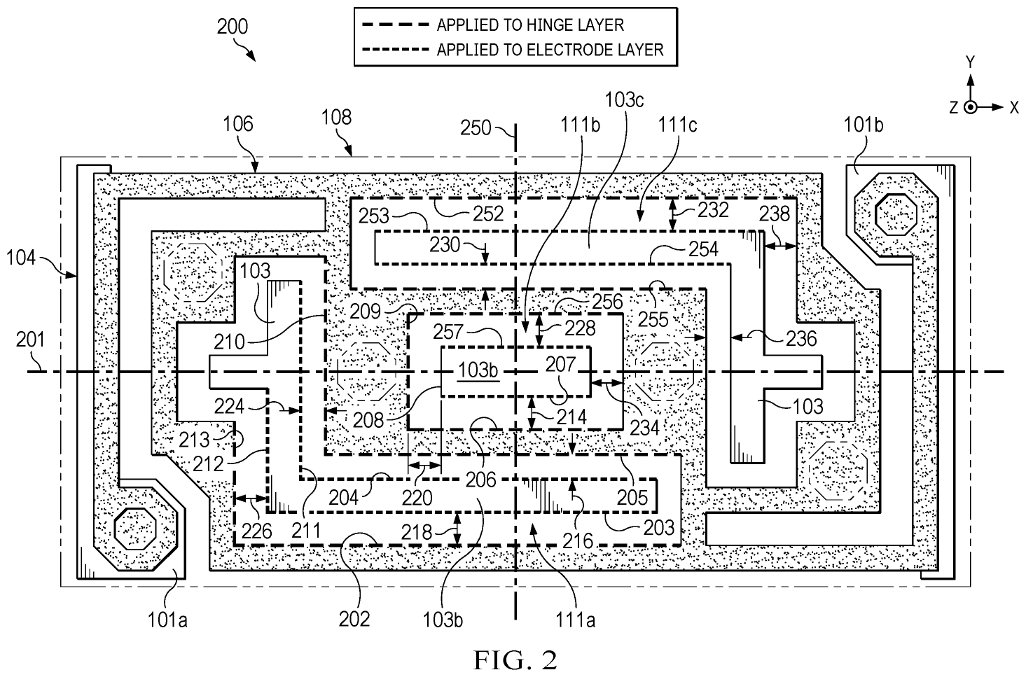

Electrode layer 104 includes multiple driving electrodes 103a-c having respective linear edges (e.g., linear edges 203, 204, 207, 208, 211, 212, 253, 254 of FIG. 2) that are spaced laterally from the nearest linear edges of hinge layer 106 (e.g., linear edges 202, 205, 206, 209, 210, 213, 255, 252 of FIG. 2), as described further herein with reference to FIG. 2. Electrode layer 104 also includes multiple driving electrodes 101a-b that each provides a surface to which a respective hinge post 105 connects and that each includes an arm over which a corresponding portion of hinge layer 106 overlaps. Because hinge posts 105 electrically couple hinge layer 106 to driving electrodes 101a-b of electrode layer 104, there will be little to no electrostatic potential between hinge layer 106 and the driving electrodes 101a-b of electrode layer 104 during operation of pixel 100.

Hinge layer 106 has voids 111a-c corresponding to driving electrodes 103a-c, respectively, such that no portion of hinge layer 106 overlaps driving electrodes 103a-c of electrode layer 104. The use of voids 111a-c within hinge layer 106 results in multiple linear edges (e.g., linear edges 202, 205, 206, 209, 210, 213, 255, 252 of FIG. 2) in hinge layer 106 that are spaced laterally from the nearest linear edges of electrode layer 104 (e.g., linear edges 203, 204, 207, 208, 211, 212, 253, 254 of FIG. 2), as described further herein with reference to FIG. 2.

Circuitry (not shown) in substrate 102 applies first electric signals to driving electrodes 101a-b, which is transmitted to hinge layer 106 through hinge posts 105. Circuitry in substrate 102 (not shown) also applies second electrical signals to driving electrodes 103a-c of electrode layer 104. In some examples, the second electrical signals may have first and second data bits that are sequentially applied, wherein the first bit is applied to centermost electrode 103b and, thereafter, the second bit is applied to the outermost electrodes 103a, 103c. The first and second applied electrical signals may be configured to generate fringe-field electrostatic potential between driving electrodes 103a-c and corresponding nearest portions of hinge layer 106.

The term “fringe-field” as used herein refers to an arrangement in which the linear edges of driving electrodes 103a-c are laterally offset from corresponding nearest linear edges of the hinge layer 106, such that no portion of hinge layer 106 overlaps any portion of the driving electrodes 103a-c of electrode layer 104. Certain fringe-field arrangements allow significant ranges of displacement of the hinge layer 106, while avoiding an unstable collapse or pull-in condition, where hinge layer 106 comes in contact with electrode layer 104. Fringe-field arrangements may be distinguished, for example, from different configurations in which parallel electrodes completely overlap one another and are electrically isolated from one another, such that they can be electrically driven to create an overlapping electrostatic potential therebetween. Such an overlapping arrangement can limit the operational range of pixel displacement, due at least in part to a possible increased risk of a collapse or pull-in condition.

Some fringe-field arrangements may be sensitive to misalignment between layers. For example, in certain designs which apply the same lateral spacing between the nearest edges of offset parallel layers, a certain degree of misalignment may have an additive effect that creates a lateral force moment in the direction of the misalignment. The lateral force moment caused by misalignment can be of sufficient magnitude to cause undesired tilting of a suspended structure om the direction of the misalignment. Limiting undesired tilt can be important in some applications, particularly where undesired tilt can be large enough to reduce optical efficiency or even cause a pixel failure.

Certain examples disclosed herein can reduce the sensitivity to misalignment between electrode layer 104 and hinge layer 106, thereby reducing undesired tilt of pixel 100 during operation, among other technical advantages. The sensitivity to misalignment can be reduced, for example, by compensation arrangements that apply varying or asymmetric spacing in the lateral gaps between electrode layer 104 and hinge layer 106, as described further below. Some examples disclosed herein incorporate an odd number of lateral gaps on each side of a centerline of pixel 100, in which a first lateral gap (closest to the centerline) and a second lateral gap (furthest from centerline) are both increased to reduce their effect if misaligned, while a third lateral gap (between the first and second lateral gaps) is decreased to increase its effect if misaligned. Thus, in the event of certain misalignments, the first and second lateral gaps may have increased distances, thereby producing a weaker fringe-field electrostatic potential, while the third or “middle” lateral gap may have a decreased distance, thereby producing a stronger fringe-field electrostatic potential and thus increasing its compensatory effect. Such example compensatory spacing, in which the lateral gaps are not all equal to one another, may reduce lateral moments generated as a result of misalignment of hinge layer 106 relative to electrode layer 104. As described further below, this compensatory effect may be applied and optimized for various pixel arrangements.

Pixel 100 may be configured for use with Phase Spatial Light Modulation (PSLM), for example. PSLM is a form of spatial light modulation where the phase of each pixel in an array of pixels determines the phase of the light transmitted by that pixel relative to light transmitted by other pixels in the same array. For example, a PSLM device may be configured to displace one or more pixels of an array by a fraction of a wavelength (e.g., one quarter wavelength) of an incident light beam. The controlled displacement of a pixel can result in the light transmitted by the pixel to be out of phase (e.g., by a quarter wavelength) from the light transmitted by any unshifted pixel(s) of the same array. The light transmitted from shifted and unshifted pixels of the same array can interfere in a controllable manner that directs the combined light.

PSLM devices may incorporate a wide range of technologies including, for example, a liquid crystal device (LCD), liquid crystal on silicon (LCOS), or a microelectromechanical system (MEMS), such as a phase light modulator (PLM). In some examples, a PSLM device can include an array of pixels that can be individually actuated to displace in a direction normal to an array plane, such that each pixel is capable of piston-mode actuation and hence may be deemed a “piston-mode actuator.” Certain PSLM devices may have thousands or even millions of individually controllable pixels, for example. Each pixel can impart a respective optical phase delay depending on an electrical signal applied to the pixel, thereby changing the shape of the optical wavefront which is incident on the device. The PSLM can impart a linear phase delay on a wavefront which has the effect of steering the beam in a different direction. A PSLM can also impart a curved wavefront which can focus the wavefront similar to a lens. Certain PSLM devices can be quickly reconfigured to steer or focus a beam to a desired direction or focus to a desired plane.

In some applications, a PSLM device can project an image based on interference of the reflected coherent light directed by pixels of different phases. The image projected by a PSLM device can have several uses. For example, the PSLM projected image can scan a scene for a Light Detection And Ranging (LIDAR) system to aid in detection of objects. In other uses, a user views the PSLM projected image directly, such as the projection of a heads-up display on the windshield of a car, for example. The PSLM can also produce a hologram, for example, in which the image in the focal plane is created through interference based on relative positions of micromirrors. In certain High Dynamic Range (HDR) applications, a PLSM is used to illuminate a Spatial Light Modulate (SLM).

FIG. 2 is view 200 (aligned with the z-axis) of the pixel 100 of FIG. 1, in which is shown respective outlines of layers 104,106, 108. For descriptive purposes, FIG. 2 shows a first centerline 201 that bisects pixel 100 (including each layer 104, 106, 108 thereof) along a plane parallel to the x-axis; and FIG. 2 further shows a second centerline 250 that bisects pixel 100 along a plane parallel to the y-axis, such that the first and second centerlines 201, 250 are perpendicular to one another.

FIG. 2 shows respective outlines of driving electrodes 103a, 103b, 103c relative to voids 111a, 111b, 111c of hinge layer 106. As shown in FIG. 2, the driving electrodes 103a-c and voids 111a-c are arranged such that no solid portion of hinge layer 106 overlaps any portion of driving electrodes 103a-c. Driving electrodes 103a-c have linear edges (e.g., linear edges 203, 204, 207, 208, 211, 212, 253, 254) positioned proximate to corresponding nearest linear edges of hinge layer 106 (e.g., linear edges 202, 205, 206, 209, 210, 213, 255, 252). The proximity of these edges can facilitate generating fringe-field electrostatic potential therebetween responsive to the application of electrical signals applied thereto, as described with reference to FIG. 1. For purposes of illustration, FIG. 2 represents certain relevant linear edges of layers 104, 106 as dotted lines; and FIG. 2 provides a key indicating the differentiation applied in the dotted lines between layers 104, 106.

The driving electrodes 103a, 103b, or 103c of electrode layer 104 can collectively have a certain odd number (e.g., 3 or greater) of linear electrode edges substantially parallel to and on the same side of centerline 201; and hinge layer 106 may have a certain odd number (e.g., 3 or greater) of linear hinge edges substantially parallel to and on the same side of centerline 201. As used herein, lines or planes are “substantially parallel” to one another if they do not intersect, or if any intersection therebetween is at an angle less than 5 degrees.

In some examples, for both the electrode layer 104 and the hinge layer 106, the respective total number of odd linear edges substantially parallel to and on the same side of centerline 201 may be the same odd number greater than or equal to 3. As shown in FIG. 2, for example, hinge layer 106 includes three linear edges 202, 205, 206 that are all on the same side of, and are all substantially parallel to, the first centerline 201. Hinge layer 106 further includes three linear edges 252, 255, 256 that are all on the opposite side of, and are all substantially parallel to, the first centerline 201. The driving electrodes 103a-b of electrode layer 104 collectively include three linear edges 203, 204, 207 that are all on the same side of, and are all substantially parallel to, the first centerline 201. The driving electrodes 103b-c of electrode layer 104 further collectively include three linear edges 253, 254, 257 that are all on the opposite side of, and are all substantially parallel to, the first centerline 201.

Electrode layer 104 can be rotationally symmetric with respect to centerline 201, in which electrode layer 104 has N*2 number of linear electrode edges (e.g., linear electrode edges 203, 204, 207, 253, 254, 257) substantially parallel to centerline 201, where N is an odd number greater than or equal to 3. In the illustrated example, centerline 201 divides 3 linear electrode edges 203, 204, 207 on one side of centerline 201 from 3 linear electrode edges 253, 254, 257 on the opposite side of centerline 201. Hinge layer 106 can likewise be rotationally symmetric with respect to centerline 201, in which hinge layer 106 has N*2 number of linear hinge edges (e.g., linear hinge edges 202, 205, 206, 252, 255, 256) substantially parallel to centerline 201, where N is the same odd number greater than or equal to 3. In the illustrated example, centerline 201 divides 3 linear hinge edges 202, 205, 206 on one side of centerline 201 from 3 linear hinge edges 252, 255, 256 on the opposite side of centerline 201.

The linear edges 202, 205, 206, 252, 255, 256 of hinge layer 106 are each spaced apart from a respective closest linear edge of the driving electrodes 103a-c of electrode layer 104 by a respective lateral gap distance, as measured along a respective line parallel to the y-axis. As used herein, a “lateral gap distance” measures a distance parallel to the plane containing both the x-axis and the y-axis (i.e., the x-y plane), wherein the distance represents the lateral spacing between first and second planes, the first plane aligning with a first linear side-wall edge of electrode layer 104 and the second plane aligning with a second side-wall edge of hinge layer 106, the first and second planes both being perpendicular to the x-y plane. Thus, gap 218 indicates the lateral gap distance between a plane including linear edge 202 of hinge layer 106 and a parallel plane including linear edge 203 of electrode layer 104, both planes in this example being perpendicular to an outermost planar surface of substrate 102, with the lateral gap distance being measured along a line parallel to the y-axis. Gap 216 indicates the lateral gap distance between nearest linear edges or “edge pair” 204 and 205, gap 214 indicates the lateral gap distance between linear edges 206 and 207, gap 228 indicates the lateral gap distance between linear edges 256 and 257, gap 230 indicates the lateral gap distance between linear edges 254 and 255, and gap 232 indicates the lateral gap distance between linear edges 252 and 253. The gaps 214-238 shown in FIG. 2 are exaggerated for clarity and are not necessarily drawn to scale.

Referring to the second centerline 250, in this example, hinge layer 106 includes three linear edges 209, 210, 213 that are all on the same side of, and are all substantially parallel to, second centerline 250. The driving electrodes 103a-c of electrode layer 104 collectively include three linear edges 208, 211, 212 that are all on the opposite side of, and are all substantially parallel to, the second centerline 250. Gap 220 indicates the lateral gap distance between linear edges 208 and 209, gap 224 indicates the lateral gap distance between linear edges 210 and 211, and gap 226 indicates the lateral gap distance between linear edges 212 and 213.

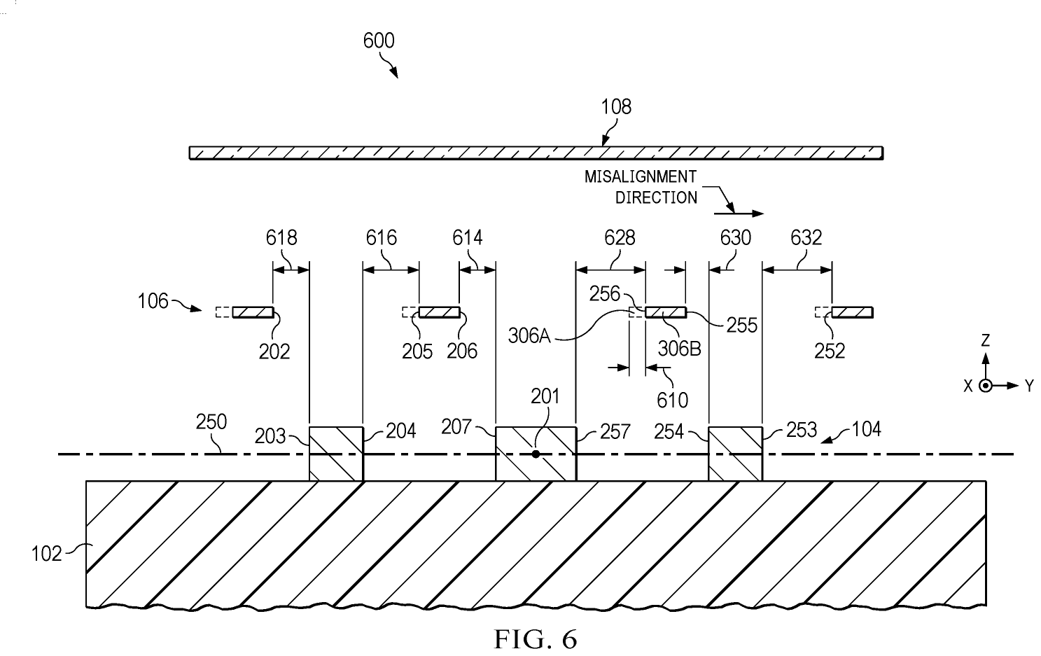

As described above, in some examples, the sensitivity to possible misalignment between layers 104 and 106 can be reduced by applying asymmetrical spacing variation in the lateral gap distances between electrode layer 104 and hinge layer 106, wherein the spacing variation provides certain compensation in the event of misalignment. The use of varying or asymmetric lateral gaps between edge pairs can result in redistributing the fringe-field electrostatic potential in a compensating manner in the event of a misalignment condition. As explained further with reference to FIG. 6, for example, a misalignment condition may result in decreasing the distance between one edge pair (e.g., edge pair 206 and 207) closest to centerline 201, while also increasing the distance between another edge pair (e.g., edge pair 252 and 253) further from centerline 201. The increased and decreased distances between edges pairs results in an increased and decreased fringe-field electrostatic potential, respectively, at those corresponding locations. Thus, the difference in proximities between edge pairs at those locations may have a compensatory or balancing effect on the lateral moment resulting from the misalignment condition. By contrast, for certain uncompensated arrangements that apply the same or “symmetrical” lateral gaps between edge pairs, a misalignment condition can have an additive effect that biases fringe-field electrostatic forces in the direction of a misalignment, thereby producing a lateral moment of sufficient magnitude to cause undesired tilt. Example effects and potential benefits of asymmetrical lateral gaps are described further herein with reference to FIG. 6 and the accompanying description of Tables 1 and 2.

In some examples, asymmetrical lateral gaps can be applied where gaps 214, 218 have substantially similar dimensions (e.g., within 5% or 10% of each other), and where gaps 214, 218 both differ substantially from gap 216. Such an example arrangement may be effected, for example, where gaps 214, 218 both indicate respective lateral gap distances that are substantially equivalent to a fixed distance plus an offset, where gap 216 indicates a lateral gap distance that is substantially equivalent to the fixed distance minus the offset, and where the offset is a nonzero value greater than 10 percent of the fixed distance. As used herein, the qualification of parameters as being “substantially equivalent” to one another means they are within +/−10 percent of one another.

In this example, gaps 214, 218, 220, 226, 228, 232, 234, 238 are substantially equivalent to one another and gaps 216, 224, 230, 236 are substantially equivalent to one another, wherein gaps 216, 224, 230, 236 are all less than gaps 214, 218, 220, 226, 228, 232, 234, 238. For example, gaps 214, 218, 220, 226, 228, 232, 234, 238 may each be substantially equivalent to 0.45 microns or “μm” (e.g., a fixed distance of 0.35 μm plus a 0.10 μm offset) and gaps 216, 224, 230, 236 may each be substantially equivalent to 0.25 μm (e.g., the same fixed distance of 0.35 μm minus the same 0.10 μm offset). As another example, gaps 214, 218, 220, 226, 228, 232, 234, 238 may each be substantially equivalent to 0.40 μm (e.g., a fixed distance of 0.35 μm plus a 0.05 μm offset) and gaps 216, 224, 230, 236 may each be substantially equivalent to 0.30 μm (e.g., the same fixed distance of 0.35 μm minus the same 0.05 μm offset). As another example, gaps 214, 218, 220, 226, 228, 232, 234, 238 may each be substantially equivalent to 0.50 μm (e.g., a fixed distance of 0.35 μm plus a 0.15 μm offset) and gaps 216, 224, 230, 236 may each be substantially equivalent to 0.20 μm (e.g., the same fixed distance of 0.35 μm minus the same 0.15 μm offset). However, any suitable compensating arrangement may be used, in which the relevant lateral gap distances are not all substantially equivalent to one another.

Although FIGS. 1 and 2 show a rectangular-shaped pixel 100 having three lateral gaps of varying distances on both sides of a pixel centerline (201 or 250), various other arrangements can be used to compensate against the effects of certain misalignments. For example, certain examples may include a pixel having a rectangular-shaped outer surface and five asymmetric lateral gaps distances on both sides of a pixel centerline. Other pixels may have an outer surface that has more or less than four linear sides (e.g., a triangle or an octagon). Some examples may include a pixel designed to actuate in a manner other than a piston mode. FIGS. 3 and 4 show examples of alternative pixels (300 and 400, respectively) that each have square-shaped outward-facing surfaces and more than three lateral gap distances between paired edges of different layers. Such alternative examples can similarly apply asymmetrical lateral gaps between fringe-field edge pairs of different layers, which can result in redistributing the fringe-field electrostatic potential in a compensating manner in the event of a misalignment condition. More specifically, the redistribution of fringe-field electrostatic potential may have a compensatory or balancing effect on the lateral moment resulting from the misalignment condition, thereby reducing the risk of undesired pixel tilt.

FIG. 3 is a view (aligned with the z-axis) of an alternative pixel 300 having square outer dimensions. In this example, pixel 300 includes an electrode layer 304 on a substrate (not explicitly shown), a hinge layer 306 physically and electrically coupled to the electrode layer 304, and a mirror layer 308 physically and electrically coupled to the hinge layer 306. The mirror layer 308 includes a square-shaped mirror. Pixel 300 also has three pairs of linear edges (312-317) on the same side of a first centerline 301, three pairs of linear edges (224-329) on the opposite side of the first centerline 301, three pairs of linear edges (318-323) on the same side of a second centerline 349, and three pairs of linear edges (330-335) on the opposite side of the second centerline 349. The gaps 350-361 shown in FIG. 3 between linear edge pairs are exaggerated for clarity and are not necessarily drawn to scale. Notwithstanding the different structural arrangement shown in FIG. 3, the electrode layer 304, hinge layer 306, and mirror layer 308 may be substantially similar in function to electrode layer 104, hinge layer 106, and mirror layer 108 of FIG. 1.

Electrode layer 304 includes three linear edges 313, 314, 317 that are all on the same side of, and are all substantially parallel to, a first centerline 301 of pixel 300. First centerline 301 is parallel to the x-axis. Hinge layer 306 includes three linear edges 312, 315, 316 that are all on the same side of first centerline 301 as linear edges 313, 314, 317 of electrode layer 304. The lateral gap distance 350 and 352 (between nearest-edge pair 312 and 313 and between nearest-edge pair 316 and 317, respectively) are substantially equivalent to one another, with both lateral gap distances being larger than the lateral gap distance 351 between nearest-edge pair 314 and 315. In some examples, lateral gap distance 350 (closest to first centerline 301) and lateral gap distance 352 (furthest from first centerline 301) are both substantially equivalent to a fixed distance plus an offset; and the lateral gap distance 351 is substantially equivalent to the same fixed distance minus the same offset. As explained above, such an example asymmetric arrangement may reduce the effects of misalignment (e.g., along the y-axis) between electrode layer 304 and hinge layer 306.

Electrode layer 304 includes three linear edges 324, 327, 328 that are all on the opposite side of, and are all substantially parallel to, first centerline 301 of pixel 300. Hinge layer 306 includes three linear edges 325, 326, 329 that are all on the same side of first centerline 301 as linear edges 324, 327, 328 of electrode layer 304. The lateral gap distances 353, 355 (between nearest-edge pair 324 and 325 and between nearest-edge pair 328 and 329, respectively) are substantially equivalent to one another, with both lateral gap distances being larger than the lateral gap distance 354 between nearest-edge pair 326 and 327. In some examples, lateral gap distance 353 (closest to first centerline 301) and lateral gap distance 355 (furthest from first centerline 301) are both substantially equivalent to a fixed distance plus an offset; and lateral gap distance 354 is substantially equivalent to the same fixed distance minus the same offset. As explained above, such an example asymmetric arrangement may reduce the effects of misalignment (e.g., along the y-axis) between electrode layer 304 and hinge layer 306.

Electrode layer 304 further includes three linear edges 318, 321, 322 that are all on the same side of, and are all substantially parallel to, a second centerline 349 of pixel 300. Second centerline 349 is parallel to the y-axis (and hence is perpendicular to first centerline 301). Hinge layer 306 includes three linear edges 319, 320, 323 that are all on the same side of second centerline 349 as linear edges 318, 321, 322 of electrode layer 304. The lateral gap distance 356 between nearest-edge pair 318 and 319 and the lateral gap distance 358 between nearest-edge pair 322 and 323 are substantially equivalent to one another, with both being larger than the lateral gap distance 357 between nearest-edge pair 320 and 321. In some examples, lateral gap distance 356 (closest to second centerline 349) and lateral gap distance 358 (furthest from second centerline 349) are both substantially equivalent to a fixed distance plus an offset; and lateral gap distance 357 is substantially equivalent to the same fixed distance minus the same offset. Such an example arrangement may reduce the effects of misalignment (e.g., along the x-axis) between electrode layer 304 and hinger layer 306.

Electrode layer 304 further includes three linear edges 330, 333, 334 that are all on the opposite side of, and are all substantially parallel to, second centerline 349 of pixel 300. Hinge layer 306 includes three linear edges 331, 332, 335 that are all on the same side of second centerline 349 as linear edges 330, 333, 334 of electrode layer 304. The lateral gap distance 359 between nearest-edge pair 330 and 331 and the lateral gap distance 361 between nearest-edge pair 334 and 335 are substantially equivalent to one another, with both being larger than the lateral gap distance 360 between nearest-edge pair 332 and 333. In some examples, lateral gap distances 359 (closest to second centerline 349) and lateral gap distance 361 (furthest from second centerline 349) are both substantially equivalent to a fixed distance plus an offset; and the lateral gap distance 360 is substantially equivalent to the same fixed distance minus the same offset. Such an example arrangement may reduce the effects of misalignment (e.g., along the x-axis) between electrode layer 304 and hinger layer 306.

FIG. 4 is a view (aligned with the z-axis) of an alternative pixel 400 having square outer dimensions and five pairs of linear edges (412-421) on one side of a centerline 401 and five pairs of linear edges (422-431) on the opposite side of centerline 401. In this example, pixel 400 includes an electrode layer 404 on a substrate (not explicitly shown), a hinge layer 406 physically and electrically coupled to the electrode layer 404, and a mirror layer 408 physically and electrically coupled to the hinge layer 406. The mirror layer 408 includes a square-shaped mirror. The gaps 450-459 shown in FIG. 4 between linear edge pairs are exaggerated for clarity and are not necessarily drawn to scale. Notwithstanding the different structural arrangement shown in FIG. 4, the electrode layer 404, hinge layer 406, and mirror layer 408 may be substantially similar in function to electrode layer 104, hinge layer 106, and mirror layer 108 of FIG. 1.

Electrode layer 404 includes five linear edges 413, 414, 417, 418, 421 that are all on the same side of, and are all substantially parallel to, centerline 401. Centerline 401 is parallel to the x-axis. Hinge layer 406 includes five linear edges 412, 415, 416, 419, 420 that are all on the same side of centerline 401 as linear edges 413, 414, 417, 418, 421 of electrode layer 404. The lateral gap distances 450, 452, 454, (between nearest-edge pairs 412-413, 416-417, and 420-421, respectively) are substantially equivalent to one another; and the lateral gap distances 451, 453 (between nearest-edge pairs 414-415 and 418-419, respectively) are substantially equivalent to one another, while also being substantially different from gap distances 450, 452, 454. In some examples, the lateral gap distances 450, 452, 454 are all substantially equivalent to a fixed distance plus an offset; and the lateral gap distances 451, 453 are both substantially equivalent to the same fixed distance minus the same offset. Such an example arrangement may reduce the effects of misalignment (e.g., along the y-axis) between electrode layer 404 and hinge layer 406.

Electrode layer 404 also includes five linear edges 422, 425, 426, 429, 430 that are all on the opposite side of, and are all substantially parallel to, centerline 401. Hinge layer 406 also includes five linear edges 423, 424, 427, 428, 431 that are all on the same side of centerline 401 as linear edges 422, 425, 426, 429, 430 of electrode layer 404. The lateral gap distances 455, 457, 459 (between nearest-edge pairs 422-423, 426-427, and 430-431, respectively) are substantially equivalent to one another; and the lateral gap distances 456, 458 (between nearest-edge pairs 424-425 and 428-429, respectively) are substantially equivalent to one another, while also being substantially different lateral gap distances 455, 457, 459. In some examples, the lateral gap distances 455, 457, 459 are all substantially equivalent to a fixed distance plus an offset; and the lateral gap distances 456, 458 are both substantially equivalent to the same fixed distance minus the same offset. Such an example arrangement may reduce the effects of misalignment (e.g., along the y-axis) between electrode layer 404 and hinge layer 406.

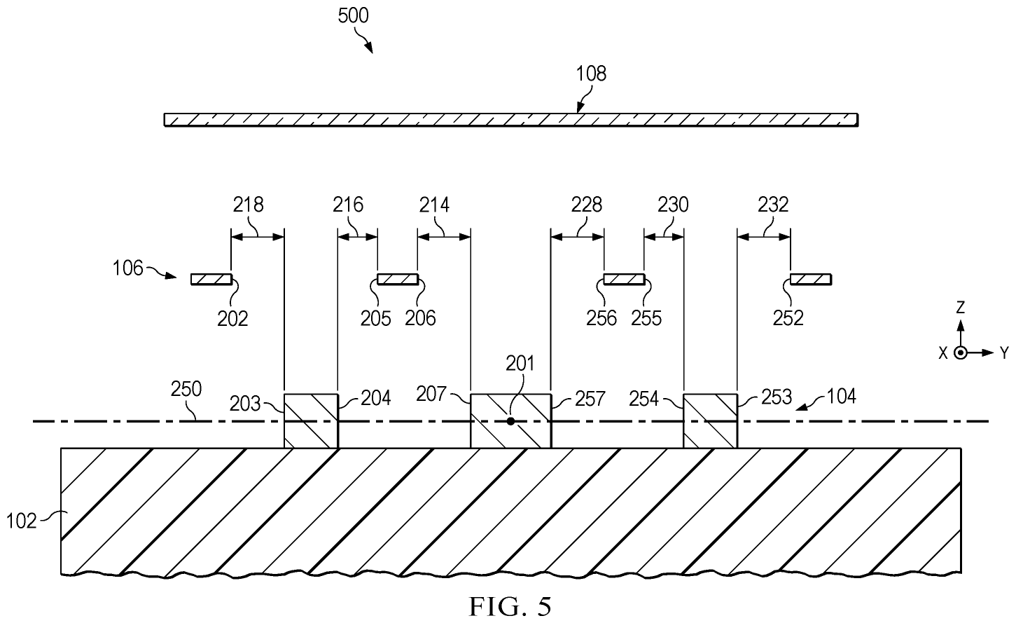

FIG. 5 is a cross-sectional view 500 of a portion of the pixel 100 of FIG. 1 under an aligned condition of hinge layer 106 relative to hinge layer 106. The illustrated cross section of pixel 100 is aligned with a plane that includes second centerline 250. As shown in view 500, gap 218 indicates the lateral gap distance between a plane aligned with linear edge 202 of hinge layer 106 and a plane parallel thereto and aligned with the nearest linear edge 203 of electrode layer 104. Gap 216 indicates the lateral gap distance (along a plane parallel to the x-y plane) between the plane aligned with linear edge 205 of hinge layer 106 and the plane parallel thereto and aligned with the nearest linear edge 204 of electrode layer 104. Gap 214 indicates the lateral gap distance between the plane aligned with linear edge 206 of hinge layer 106 and the plane parallel thereto and aligned with the nearest linear edge 207 of electrode layer 104. The gaps 214, 216, 218, 228, 230, 232 shown in FIG. 5 are exaggerated for clarity and are not necessarily drawn to scale.

In some examples, gaps 218 and 214 may be substantially equivalent to a fixed distance plus an offset, with gap 216 being substantially equivalent to the fixed distance minus the offset, and where the offset is a nonzero value greater than 10 percent of the fixed distance. Such an example arrangement may reduce the effects of a misalignment (e.g., along the y-axis) between electrode layer 104 and hinge layer 106.

On the opposite side of centerline 201, gap 228 indicates the lateral gap distance (along a plane parallel to the x-y plane) between a plane aligned with linear edge 256 of hinge layer 106 and a plane parallel thereto and aligned with the nearest linear edge 257 of electrode layer 104. Gap 230 indicates the lateral gap distance between the plane aligned with linear edge 255 of hinge layer 106 and the plane parallel thereto and aligned with the nearest linear edge 254 of electrode layer 104. Gap 232 indicates the lateral gap distance between the plane aligned with linear edge 252 of hinge layer 106 and the plane parallel thereto and aligned with the nearest linear edge 253 of the electrode layer 104.

In some examples, gaps 228 and 232 may be substantially equivalent to a fixed distance plus an offset, with gap 230 being substantially equivalent to the fixed distance minus the offset, where the offset is a nonzero value greater than 10 percent of the fixed distance. Such an example arrangement may further reduce the effects of a misalignment (e.g., along the y-axis) between electrode layer 104 and hinge layer 106.

Table 1 below provides representative values that can be used to calculate the respective force of the fringe-field electrostatic potential generated at each gap by the corresponding nearest-edge pairs-namely, nearest-edge pairs 202-203 (gap 218), 204-205 (gap 216), 206-207 (gap 214), 256-257 (gap 228), 254-255 (gap 230), and 252-253 (gap 232). The top row refers to the nearest-edge pair by its gap reference number. The second row indicates the lateral gap distance between corresponding nearest-edge pairs. The third row indicates a force constant per unit length (C). The fourth row indicates the total length (L) shared by the corresponding nearest-edge pair. The fifth row indicates the calculated force (F=C*L) of the fringe-field electrostatic potential in a direction parallel to the z-axis (and hence normal to the outward facing surface of substrate 102).

TABLE 1

| Gap No. | 218 | 216 | 214 | 228 | 230 | 232 |
|---|---|---|---|---|---|---|
| Lateral Gap Distance (μm) | 0.45 | 0.25 | 0.45 | 0.45 | 0.25 | 0.45 |
| Force per length unit (C) | 0.32 | 0.64 | 0.32 | 0.32 | 0.64 | 0.32 |
| Edge Length (L) | 4.8 | 4 | 1.8 | 1.8 | 4 | 4.8 |
| F = C*L | 1.52 | 2.55 | 0.57 | 0.57 | 2.55 | 1.52 |

The respective lateral moment (e.g., in the positive or negative direction of the y-axis) generated by the forces shown in Table 1 is proportional to the distance between the respective gap 214-232 and the centerline 201 perpendicular thereto. In more general terms, if two gaps have the same lateral gap distance, the one further from the centerline will have the greater lateral moment and thus poses a greater risk at contributing to undesired tilt of pixel 100. Because FIG. 5 illustrates pixel 100 under an aligned condition, the opposing lateral moments of gaps 218 and 232 furthest from centerline 201 cancel one another, the opposing lateral moments of gaps 214 and 228 closest to centerline 201 cancel one another, and the opposing lateral moments of the middle gaps 216 and 230 cancel one another. The result is that there is zero or “balanced” net lateral moment in either the positive or negative direction of the y-axis under this aligned condition. The balanced result may be represented mathematically as follows:

$$M 1 = R {1}^{*} ( 0.57 - 0.57 ) = {0.8}^{*} ( 0 ) = 0$$

$$M 2 = R {2}^{*} ( 2.55 - 2.55 ) = {1.1}^{*} ( 0 ) = 0$$

$$M 3 = R {3}^{*} ( 1.52 - 1.52 ) = {2.2}^{*} ( 0 ) = 0$$

$$Total Lateral Moment = M 1 + M 2 + M 3 = 0 + 0 + 0 = 0 ,$$

where M1 is the net moment of gaps 214 and 228 (closest to centerline 201), R1 is the distance of gaps 214 and 228 from centerline 201, M2 is the net moment of middle gaps 216 and 230, R2 is the distance of gaps 216 and 230 to centerline, M3 is the net moment of gaps 218 and 232 furthest from centerline 201, and R3 is the distance of gaps 218 and 232 from centerline.

The aligned alignment condition along the y-axis shown in FIG. 5 results in gaps 214 and 218 being substantially equivalent to a fixed distance plus an offset (e.g., 0.35 μm+0.10 μm=0.45 μm), while also resulting in gap 230 being substantially equivalent to the fixed distance minus the (e.g., 0.35 μm−0.10 μm=0.25 μm). On the opposite side of centerline 201, the aligned condition along the y-axis shown in FIG. 5 results in gaps 228 and 232 being substantially equivalent to the same fixed distance plus the same offset (e.g., 0.35 μm+0.10 μm=0.45 μm), while also resulting in gap 330 being substantially equivalent to the same fixed distance minus the same offset (e.g., 0.35 μm−0.10 μm=0.25 μm).

FIG. 6 is a cross-sectional view 600 of a portion of the pixel 100 of FIG. 1, in which hinge layer 106 is misaligned by 50 nanometers (shown as lateral distance 610) relative to the electrode layer 104. As shown in FIG. 6, the illustrated misalignment is in the positive direction of the y-axis, with the dotted lines 306A of hinge layer 106 indicating where the hinge layer 106 should be if aligned with respect to the electrode layer 104 (e.g., as shown in FIG. 5), and 306B indicating the misaligned location of hinge layer 106 relative to electrode layer 104. As shown in view 600, gap 618 indicates the lateral gap distance between a plane aligned with linear edge 202 of hinge layer 106 and a plane parallel thereto and aligned with linear edge 203 of electrode layer 104. Gap 616 indicates the lateral gap distance between the plane aligned with linear edge 204 of electrode layer 104 and the plane parallel thereto and aligned with linear edge 205 of hinge layer 106. Gap 614 indicates the lateral gap distance between the plane aligned with linear edge 206 of hinge layer 106 and the plane parallel thereto and aligned with linear edge 207 of electrode layer 104. On the opposite side of centerline 201, gap 628 indicates the lateral gap distance between nearest-edge pair 256 and 257, gap 630 indicates the lateral gap distance between nearest-edge pair 254 and 255, and gap 632 indicates the lateral gap distance between nearest-edge pair 252 and 253.

Table 2 below provides representative values that can be used to calculate the respective force of the fringe-field electrostatic potential generated at each gap by the corresponding nearest edge pairs-namely, nearest edge pairs 202-203 (gap 618), 204-205 (gap 616), 206-207 (gap 614), 256-257 (gap 628), 254-255 (gap 630), and 252-253 (gap 632). The rows of Table 2 are arranged similar to Table 1 above.

TABLE 2

| Gap No. | 618 | 616 | 614 | 628 | 630 | 632 |
|---|---|---|---|---|---|---|
| Lateral Gap Distance (μm) | 0.4 | 0.3 | 0.4 | 0.5 | 0.2 | 0.5 |
| Force per length unit (C) | 0.37 | 0.53 | 0.37 | 0.27 | 0.78 | 0.27 |
| Edge Length (L) | 4.8 | 4 | 1.8 | 1.8 | 4 | 4.8 |
| F = C*L | 1.77 | 2.11 | 0.67 | 0.49 | 3.13 | 1.31 |

The respective lateral moment (e.g., in the positive or negative direction of the y-axis) generated by the forces shown in Table 2 is proportional to the distance between the respective gap 614-632 and the centerline 201 perpendicular thereto. Because FIG. 6 illustrates pixel 100 under a misaligned condition, the result is that there will be a nonzero total lateral moment. However, as disclosed herein, the use of asymmetrical spacings between nearest-edge pairs of layers 104 and 106 can at least partially compensate for certain misalignment. Such compensation can reduce the total lateral moment caused by a misalignment condition, thereby potentially mitigating the risk of undesired tilt.

In this example, the total lateral moment generated by the example misalignment condition shown in FIG. 6 may be calculated as follows:

$$M 1 = R {1}^{*} ( 0.67 - 0.49 ) = {0.8}^{*} ( 0.18 ) = 0.14$$

$$M 2 = R {2}^{*} ( 2.11 - 3.13 ) = {1.1}^{*} ( - 1.02 ) = - 1.12$$

$$M 3 = R {3}^{*} ( 1.77 - 1.31 ) = {2.2}^{*} ( 0.46 ) = 1.02$$

$$Total Lateral Moment = M 1 + M 2 + M 3 = 0.14 - 1.12 + 1.02 = 0.04 ,$$

where M1 is the net moment of gaps 614 and 628 (closest to centerline 201), R1 is the distance of gaps 614 and 628 from centerline 201 (due in part to misalignment), M2 is the net moment of middle gaps 616 and 630, R2 is the distance of gaps 616 and 630 to centerline (due in part to misalignment), M3 is the net moment of gaps 618 and 632 furthest from centerline 201, and R3 is the distance of gaps 618 and 632 from centerline (due in part to misalignment).

Thus, the misalignment condition shown in FIG. 6 results in a calculated total lateral moment of 0.04 (as measured in units of force per length, times edge length, times moment arm, or “nN-μm”). While 0.04 nN-μm is a nonzero value, it nevertheless may be sufficiently low to avoid causing undesired tilt when pixel 100 is actuated. Furthermore, the calculated total lateral moment of 0.04 nN-μm demonstrates a considerable improvement over a symmetrical design that does not apply the compensatory spacing shown in FIG. 6. For example, a symmetrical redesign of pixel 100, in which all gaps identified in FIG. 2 (e.g., gaps 214, 216, 218, 228, 230, 232, etc.) are modified to be the same dimension (e.g., 0.35 μm), would result in a total lateral moment of at least 1.20 nN-μm under the same misalignment condition (i.e., a 50 nanometer misalignment in the negative direction of the y-axis). The total lateral moment of 1.20 nN-μm for such a symmetrical design is 30 times greater than the total lateral moment of 0.04 nN-μm achieved by the compensatory spacing of example pixel 100.

The misalignment along the y-axis shown in FIG. 6 results in gaps 614 and 618 being 0.05 μm narrower than corresponding gaps 214 and 218 shown in FIG. 5, and further results in gap 616 being 0.05 μm wider than corresponding gap 216 shown in FIG. 5. One the opposite side of centerline 201, the misalignment shown in FIG. 6 results in gaps 628 and 632 being 0.05 μm wider than corresponding gaps 228 and 232 shown in FIG. 5, and further results in gap 630 being 0.5 μm narrower than corresponding gap 230 in FIG. 5. Thus, the example misalignment shown in FIG. 6 results in gaps 614 and 618 being substantially equivalent to a fixed distance plus an offset (e.g., 0.35 μm+0.05 μm=0.40 μm), while also resulting in gap 616 being substantially equivalent to the same fixed distance minus the same offset (e.g., 0.35 μm−0.05 μm=0.30 μm). On the opposite side of centerline 201, the example misalignment shown in FIG. 6 results in gaps 628 and 632 being substantially equivalent to a fixed distance plus an offset (e.g., 0.35 μm+0.05 μm=0.40 μm), while also resulting in gap 630 being substantially equivalent to the same fixed distance minus the same offset (e.g., 0.35 μm−0.05 μm=0.30 μm).

The effects of the example misalignment shown in FIG. 6 are at least partially compensated for by the resultant lateral gap distances spacing apart nearest edge pairs of layers 104 and 106. For example, the example misalignment results in gap 630 having a decreased measurement relative to gap 230, thereby causing a stronger fringe-field electrostatic potential closer to centerline 201. In addition, the misalignment shown results in increased gaps 628 and 632 to have a greater measurement relative to gaps 228 and 232, respectively, thereby causing weaker fringe-field electrostatic potential at those respective locations. Thus, the calculated use of different offsets for the lateral gaps between edge pairs can result in redistributing the fringe-field electrostatic potential in a compensating manner. Such compensation can potentially reduce undesired tilt that can otherwise arise due to misalignment and in the absence of such compensation.

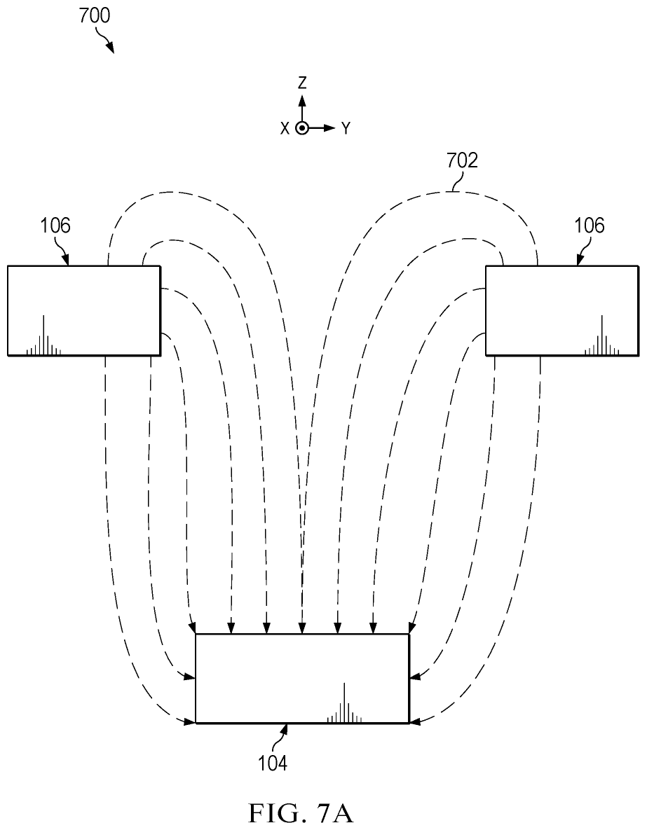

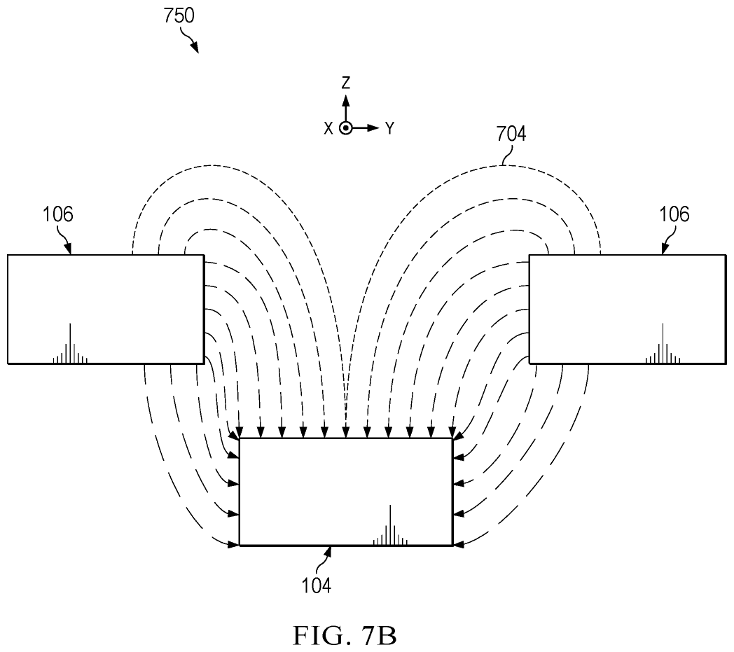

FIGS. 7A-7B show respective example states (700, 750) of pixel 100 responsive to fringe-field electrostatic potential applied between electrode layer 104 and hinge layer 106. More specifically, FIG. 7A illustrates the relative positioning of hinge layer 106 at a first state 700, and FIG. 7B illustrates the relative positioning of hinge layer 106 at a second state 750, wherein pixel 100 is displaced in the second state 750 relative to the first state 700. The displacement of pixel 100 can be effected by applying respective electric signals to the hinge layer 106 or to the driving electrodes 103a-c of electrode layer (or both). The applied electric signals may be configured to generate fringe-field electrostatic potential (shown as field lines 702, 704) sufficient to cause pixel 100 to transition from the first state 700 to the second state 750, and vice versa. For example, to transition pixel 100 from the first state 700 shown in FIG. 7A to the second state 750 shown in FIG. 7B, a voltage may be applied to driving electrodes 103a-c of electrode layer 104 and a reference voltage (e.g., ground) may be applied to hinge layer 106 (e.g., via driving electrodes 101a-b and hinge posts 105). An increase in the resultant electrostatic force may pull the illustrated portion of hinge layer 106 toward the driving electrodes 103a-c of electrode layer 104, which in turn displaces the mirror layer 108 coupled to the hinge layer 106 by a commensurate amount. Conversely, to transition pixel 100 from the second state 750 shown in FIG. 7B to the first state 700 shown in FIG. 7A, the same reference voltage (e.g., ground) may be applied to both the hinge layer 106 and the driving electrodes 103a-c of electrode layer 104.

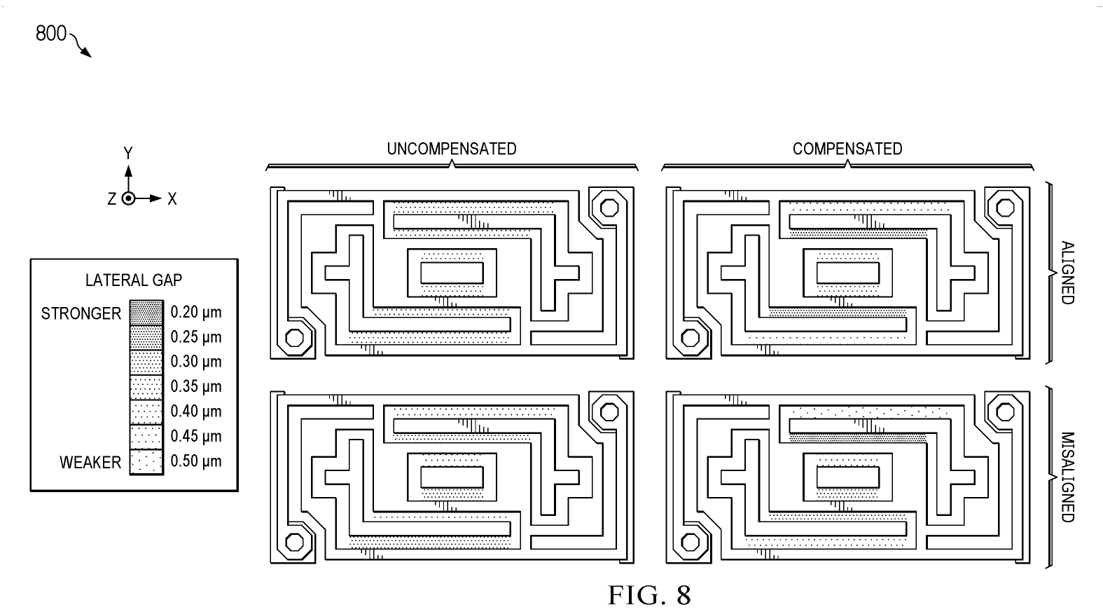

FIG. 8 is a matrix 800 showing comparative representations of four example pixels, each applying either compensated or uncompensated lateral gaps distances under either an aligned or misaligned condition. A key on the left of the matrix indicates the relative fringe-field strength corresponding to certain lateral gap distances incorporated by the different pixels of matrix 800. The upper-left pixel incorporates the same uncompensated lateral gap distances under an aligned condition, wherein the relevant lateral gap distances are symmetric with one another in that each is represented as being approximately 0.35 μm (and hence in the middle of the greyscale shown in the key).

The bottom-left pixel incorporates the same lateral gap distances as the upper-left pixel, albeit under a misaligned condition. Specifically, due to a 50 nanometer misalignment in the negative direction of the y-axis, the six lateral gap distances of the bottom-left pixel are as follows (listed from top to bottom): 0.40 μm, 0.30 μm, 0.40 μm, 0.30 μm, 0.40 μm, and 0.30 μm. The illustrated misalignment for the bottom-left pixel has an additive effect that can produce a total lateral moment of sufficient force to risk causing undesired tilt (e.g., in the negative direction of the y-axis) when the pixel is actuated.

The upper-right pixel incorporates compensated lateral gap distances under an aligned condition. Specifically, the six lateral gap distances of the upper-right pixel are as follows (listed from top to bottom): 0.45 μm, 0.25 μm, 0.45 μm, 0.45 μm, 0.25 μm, and 0.45 μm. In this example, when the pixel is actuated, the cumulative fringe-field electrostatic potential is the same on both sides of the horizontal centerline of the pixel—i.e., the aligned condition produced a balanced result with no lateral moment.

The lower-right pixel incorporates the compensated lateral gap distances of the upper-right pixel, albeit under a misaligned condition. Specifically, due to a 50 nanometer misalignment in the negative direction of the y-axis, the six lateral gap distances of the lower-right pixel are as follows (listed from top to bottom): 0.50 μm, 0.20 μm, 0.50 μm, 0.40 μm, 0.30 μm, and 0.40 μm. In this example, when the pixel is actuated, the cumulative fringe-field electrostatic potential is not the same (i.e., unbalanced) on either side of the horizontal centerline of the pixel. However, the varying lateral gap distances at least partially compensates for the misalignment by reducing the total lateral moment relative to the lower-left pixel (e.g., as explained above, 0.04 nN-μm may represent a relative ˜ 1/30 reduction over a comparable uncompensated design under certain circumstances). The reduced total lateral moment can reduce the magnitude of undesired tilt of the lower-right pixel relative to the lower-left pixel.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. To aid the Patent Office, and any readers of any patent issued on this application, in interpreting the claims appended hereto, applicant notes that there is no intention that any of the appended claims invoke 35 U.S.C. § 112(f) as it exists on the date of filing hereof unless the words “means for” or “step for” are explicitly used in the claim language.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In the foregoing descriptions, for purposes of explanation, numerous specific details are set forth to provide a thorough understanding of one or more examples. However, this disclosure may be practiced without some or all of these specific details, as will be evident to one having ordinary skill in the art. In other instances, well-known process steps or structures have not been described in detail in order not to unnecessarily obscure this disclosure. In addition, while the disclosure is described in conjunction with examples, this description is not intended to limit the disclosure to the described examples. To the contrary, the description is intended to cover alternatives, modifications, and equivalents as may be included within the spirit and scope of the disclosure as defined by the appended claims.

What is claimed is:

1. An apparatus comprising:
a substrate;
an electrode layer on the substrate, the electrode layer having N linear electrode edges on a same side of a centerline of the electrode layer, N being an odd number greater than or equal to 3; and
a hinge layer having N linear hinge edges on the side of the centerline;
wherein a first edge of the linear hinge edges is spaced apart from a closest second edge of the linear electrode edges by a first lateral gap distance, and a third edge of the linear hinge edges is spaced apart from a closest fourth edge of the linear electrode edges by a second lateral gap distance different from the first lateral gap distance.

2. The apparatus of claim 1, wherein the apparatus is a piston-mode actuator.

3. The apparatus of claim 1, further comprising a mirror coupled to the hinge layer.

4. The apparatus of claim 1, wherein the first lateral gap distance is substantially equivalent to a fixed distance plus an offset and the second lateral gap distance is substantially equivalent to the fixed distance minus the offset.

5. The apparatus of claim 1, wherein a fifth edge of the linear hinge edges is spaced apart from a closest sixth edge of the linear electrode edges by a third lateral gap distance different from the second lateral gap distance.

6. The apparatus of claim 5, wherein the first and third lateral gap distances are within 5% of each other.

7. The apparatus of claim 5, wherein the first lateral gap distance is substantially equivalent to a fixed distance plus an offset, the second lateral gap distance is substantially equivalent to the fixed distance minus the offset, and the third lateral gap distance is substantially equivalent to the fixed distance plus the offset.

8. An apparatus comprising:
a substrate;
an electrode layer on the substrate, the electrode layer having N linear electrode edges on a side of a centerline of the electrode layer, N being an odd number greater than or equal to 3; and
a hinge layer coupled to the electrode layer, the hinge layer having N linear hinge edges on the side of the centerline;
wherein a first edge of the linear hinge edges is spaced apart from a closest second edge of the linear electrode edges by a first lateral gap distance substantially equivalent to a fixed distance plus an offset, and a third edge of the linear hinge edges is spaced apart from a closest fourth edge of the linear electrode edges by a second lateral gap distance substantially equivalent to the fixed distance minus the offset.

9. The apparatus of claim 8, further comprising a mirror layer coupled to the hinge layer.

10. The apparatus of claim 8, wherein the apparatus is a piston-mode actuator.

11. The apparatus of claim 8, wherein a fifth edge of the linear hinge edges is spaced apart from a closest sixth edge of the linear electrode edges by a third lateral gap distance substantially equivalent to the fixed distance plus the offset.

12. The apparatus of claim 8, wherein the hinge layer is misaligned by at least 50 nanometers along an axis perpendicular to the centerline and a fringe-field electrostatic potential between the N linear electrode edges and the N linear hinge edges has a lateral moment of less than 0.1 nN-μm.

13. The apparatus of claim 8, wherein the hinge layer is rotationally symmetric with respect to the centerline, such that the hinge layer has N*2 number of linear hinge edges substantially parallel to the centerline, the centerline dividing N linear hinge edges on one side of the centerline from N hinge edges on the opposite side of the centerline.

14. The apparatus of claim 8, wherein the electrode layer is rotationally symmetric with respect to the centerline, such that the electrode layer has N*2 number of linear hinge edges substantially parallel to the centerline, the centerline dividing N linear electrode edges on one side of the centerline from N linear electrode edges on the opposite side of the centerline.

15. The apparatus of claim 8, wherein the centerline is a first centerline, the electrode layer has a second centerline perpendicular to the first centerline, the hinge layer has N linear hinge edges on a side of the second centerline, and the electrode layer has N linear electrode edges on the side of the second centerline; and
wherein and a fifth edge of the N linear hinge edges is spaced apart from a closest sixth edge of N linear electrode edges by a first lateral gap distance substantially equivalent to the fixed distance plus the offset, and a seventh edge of the N linear hinge edges is spaced apart from a closest eight edge of the N linear electrode edges by a second lateral gap distance substantially equivalent to the fixed distance minus the offset.

16. An apparatus comprising:
a substrate;
an electrode layer on the substrate, the electrode layer having N linear electrode edges on a same side of a centerline of the electrode layer, N being an odd number greater than or equal to 3; and
a hinge layer having N linear hinge edges on the side of the centerline; and
a first post coupling the hinge layer to the electrode layer;
a mirror layer; and
a second post coupling the mirror layer to the hinge layer;
wherein a first edge of the linear hinge edges is spaced apart from a closest second edge of the linear electrode edges by a first lateral gap distance, and a third edge of the linear hinge edges is spaced apart from a closest fourth edge of the linear electrode edges by a second lateral gap distance different from the first lateral gap distance.

17. The apparatus of claim 16, wherein the first lateral gap distance is substantially equivalent to a fixed distance plus an offset, the second lateral gap distance is substantially equivalent to the fixed distance minus the offset.

18. The apparatus of claim 16, wherein the apparatus is a piston-mode actuator.

19. The apparatus of claim 16, wherein a fifth edge of the linear hinge edges is spaced apart from a closest sixth edge of the electrode edges by a third lateral gap distance within 5% of the first lateral gap distance.

20. The apparatus of claim 19, wherein the first lateral gap distance is substantially equivalent to a fixed distance plus an offset, the second lateral gap distance is substantially equivalent to the fixed distance minus the offset, and the third lateral gap distance is substantially equivalent to the fixed distance plus the offset.
